(19) United States
(12) Patent Application Publication
(10) Pub. No.: US 2025/0151547 A1
(43) Pub. Date: May 8, 2025

(54) DISPLAY APPARATUS

(71) Applicant: SAMSUNG DISPLAY CO., LTD., YONGIN-SI (KR)

(72) Inventor: Kiho Bang, Yongin-si (KR)

(21) Appl. No.: 18/778,812

(22) Filed: Jul. 19, 2024

(30) Foreign Application Priority Data
Nov. 3, 2023 (KR) 10-2023-0151026

(51) Int. Cl. H10K 59/131; H10K 59/124; H10K 59/40; H10K 102/00

(52) U.S. Cl. CPC H10K 59/131; H10K 59/124; H10K 59/40; H10K 2102/311

(57) ABSTRACT

A display apparatus includes a substrate that includes a display area, a peripheral area located outside the display area, a bendable area located in the peripheral area, and a first area located between the display area and the bendable area, an inorganic insulating layer disposed in the display area and the peripheral area, a light-emitting diode disposed in the display area, an encapsulation layer disposed on the light-emitting diode, a touch sensor layer disposed on the encapsulation layer, a power supply wiring disposed on the inorganic insulating layer and that extends from the display area to the first area and the bendable area, a sensor wiring that extends from the display area to the first area and the bendable area and overlaps the power supply wiring, and a sub-sensor wiring disposed under the sensor wiring in the first area and that overlaps the sensor wiring.

### CROSS-REFERENCE TO RELATED APPLICATION

This application claims priority under 35 U.S.C. § 119 from Korean Patent Application No. 10-2023-0151026, filed on Nov. 3, 2023 in the Korean Intellectual Property Office, the contents of which are herein incorporated by reference in their entirety.

### TECHNICAL FIELD

One or more embodiments are directed to a display apparatus.

### DISCUSSION OF THE RELATED ART

Organic light-emitting display apparatuses have attracted attention as next-generation display apparatuses due to their wide viewing angle, high contrast, and fast response time.

In general, an organic light-emitting display apparatus includes a thin-film transistor and an organic light-emitting diode formed on a substrate, and the organic light-emitting diode itself emits light. Such an organic light-emitting display apparatus can be used as a display for a small product such as a mobile phone, or can be used as a display for a large product such as a television.

### SUMMARY

One or more embodiments include a display apparatus that may prevent a short-circuit between sensor wirings that pass through a bent area. However, embodiments are not necessarily limited thereto.

According to one or more embodiments, a display apparatus includes a substrate that includes a display area, a peripheral area located outside the display area, a bendable area located in the peripheral area, and a first area located between the display area and the bendable area, an inorganic insulating layer disposed in the display area and the peripheral area, a light-emitting diode disposed in the display area, an encapsulation layer disposed on the light-emitting diode, a touch sensor layer disposed on the encapsulation layer, a power supply wiring disposed on the inorganic insulating layer and that extends from the display area to the first area and the bendable area, a sensor wiring that extends from the display area to the first area and the bendable area and that overlaps the power supply wiring, and a sub-sensor wiring disposed under the sensor wiring in the first area and that overlaps the sensor wiring.

The inorganic insulating layer may be disposed in the first area and might not be disposed in the bending area.

The display apparatus may further include an organic insulating layer interposed between the inorganic insulating layer and the light-emitting diode, wherein the sensor wiring overlaps the power supply wiring with the organic insulating layer interposed therebetween.

In the bendable area, the sensor wiring may be disposed on a top surface of the organic insulating layer.

The first area may include a first sub-area and a second sub-area located between the first sub-area and the bending area, wherein, in the first sub-area, the sensor wiring overlaps the sub-sensor wiring with an insulating layer interposed therebetween.

In the first sub-area, the sensor wiring may directly contact the sub-sensor wiring through a contact hole formed in the insulating layer.

In the second sub-area, the sensor wiring may be disposed on a top surface of the sub-sensor wiring.

The touch sensor layer may include a first insulating layer disposed on the encapsulation layer, a first conductive layer disposed on the first insulating layer, a second insulating layer disposed on the first conductive layer, and a second conductive layer disposed on the second insulating layer, wherein the insulating layer is the second insulating layer of the touch sensor layer.

The sensor wiring and the second conductive layer may include a same material, and the sub-sensor wiring and the first conductive layer may include a same material.

The first insulating layer may be disposed in the display area, the first area, and the bendable area.

The sub-sensor wiring may be disposed on the first insulating layer and extends into the bendable area.

The first insulating layer may be disposed in the display area and the first area but not in the bendable area.

The second insulating layer may be disposed in the display area and the first area but not in the bendable area.

An edge of the first insulating layer may be closer to the bendable area than an edge of the second insulating layer.

The sensor wiring may directly contact a top surface and a side surface of the sub-sensor wiring and a side surface of the first insulating layer.

The sensor wiring may directly contact a side surface of the second insulating layer.

The sensor wiring may include a first wiring portion disposed on a top surface of the second insulating layer, and a second wiring portion I disposed on the top surface of the sub-sensor wiring and spaced apart from a side surface of the second insulating layer, wherein the first wiring portion and the second wiring portion are electrically connected to each other through the sub-sensor wiring.

The second insulating layer may include a first portion and a second portion having different thicknesses. The second portion of the second insulating layer may be located closer to the bending area than the first portion of the second insulating layer, and a thickness of the second portion of the second insulating layer may be less than a thickness of the first portion of the second insulating layer.

The display apparatus may further include an organic layer disposed on the touch sensor layer and that covers the sensor wiring in the bendable area.

According to one or more embodiments, a display apparatus includes a substrate that includes a display area, a peripheral area located outside the display area, a bendable area located in the peripheral area, and a first area located between the display area and the bendable area, a power supply wiring that extends from the display area to the first area and the bendable area, a sensor wiring of a touch sensor layer, where the sensor wiring extends from the display area to the first area and the bendable area and overlaps the power supply wiring, and a sub-sensor wiring of the touch sensor layer, where the sub-sensor wiring is disposed under the sensor wiring in the first area and overlaps the sensor wiring. The first area comprises a first sub-area and a second sub-area between the first sub-area and the bendable area. In the first sub-area, the sensor wiring overlaps the sub-sensor wiring with an insulating layer interposed therebetween.

### BRIEF DESCRIPTION OF THE DRAWINGS

FIG. 1 is a schematic plan view of a display apparatus, according to an embodiment.

FIG. 2 is a schematic side view of a display apparatus, according to an embodiment.

FIG. 3 is a schematic plan view of a display apparatus, according to an embodiment.

FIG. 4 is a schematic cross-sectional view of a display apparatus, taken along line II-II′ of FIG. 1, according to an embodiment.

FIG. 5 is an equivalent circuit diagram of a light-emitting diode of a display apparatus and a sub-pixel circuit electrically connected to the light-emitting diode, according to an embodiment.

FIG. 6 is a schematic cross-sectional view of a portion of a display area of a display apparatus, according to an embodiment.

FIG. 7 is a plan view of a touch sensor layer of a display apparatus, according to an embodiment.

FIG. 8 is a schematic cross-sectional view of a touch sensor layer, taken along line III-III′ of FIG. 7, according to an embodiment.

FIG. 9 is an enlarged plan view of a portion of a peripheral area of a display apparatus and an enlarged cross-sectional view of a portion B of FIG. 1, according to an embodiment.

FIGS. 10A to 10C are schematic plan views of a power supply wiring and a sensor wiring, according to an embodiment.

FIG. 11 is a schematic cross-sectional view of a portion of a display apparatus, taken along line IV-IV′ of FIG. 9, according to an embodiment.

FIG. 12 is a schematic cross-sectional view of a portion of a display apparatus, according to a comparative example.

FIG. 13 is a schematic cross-sectional view of a portion of a display apparatus, according to an embodiment.

FIG. 14 is a schematic cross-sectional view of a portion of a display apparatus, according to an embodiment.

FIG. 15 is an enlarged cross-sectional view of a portion D of a modified embodiment of FIG. 11.

FIG. 16 is a schematic cross-sectional view of a portion of a display apparatus, according to an embodiment.

### DETAILED DESCRIPTION

Reference will now be made in detail to embodiments, examples of which are illustrated in the accompanying drawings, wherein like reference numerals may refer to like elements throughout. In this regard, the present embodiments may have different forms and should not be construed as being limited to the descriptions set forth herein. Accordingly, the embodiments are merely described below, by referring to the figures, to explain aspects of the present description.

As the disclosure allows for various changes and numerous embodiments, certain embodiments will be illustrated in the drawings and described in the detailed description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings, wherein the same or corresponding elements may be denoted by the same reference numerals throughout and a repeated description thereof is omitted.

It will be further understood that, when a layer, region, or component is referred to as being “on” another layer, region, or component, it may be directly on the other layer, region, or component, or may be indirectly on the other layer, region, or component with intervening layers, regions, or components therebetween. On the other hand, when a layer, region, or component is referred to as being “directly on” another layer, region, or component, no intervening layers, regions, or components are interposed therebetween.

It will be understood that when a layer, a region, or a component is referred to as being “connected” to another layer, region, or component, it may be “directly connected” to the other layer, region, or component and/or may be “indirectly connected” to the other layer, region, or component with other layers, regions, or components interposed therebetween. On the other hand, when a layer, region, or component is referred to as being “directly connected to” another layer, region, or component, no intervening layers, regions, or components are interposed therebetween.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

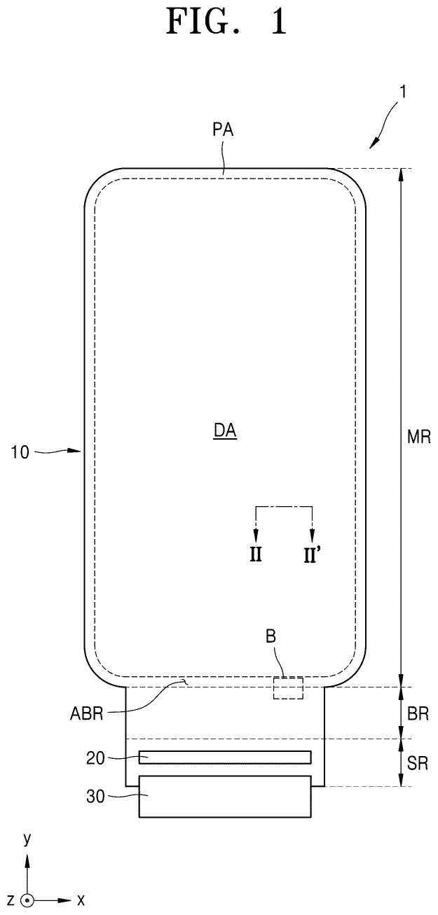

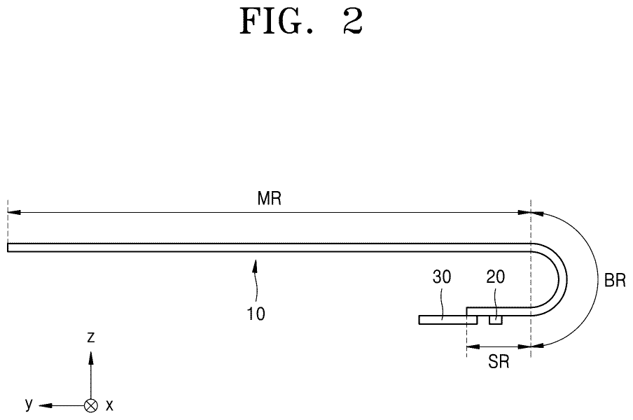

FIG. 1 is a schematic plan view of a display apparatus, according to an embodiment. FIG. 2 is a schematic side view of a display apparatus, according to an embodiment. A display apparatus according to a present embodiment is partially bent as shown in FIG. 2, but is shown as not bent in FIG. 1 for convenience.

Referring to FIGS. 1 and 2, in an embodiment, a display apparatus 1 includes a display panel 10. The display apparatus 1 may be any device that includes the display panel 10. For example, the display apparatus 1 may be any of various products, such as a smartphone, a tablet, a laptop, a television, or a billboard.

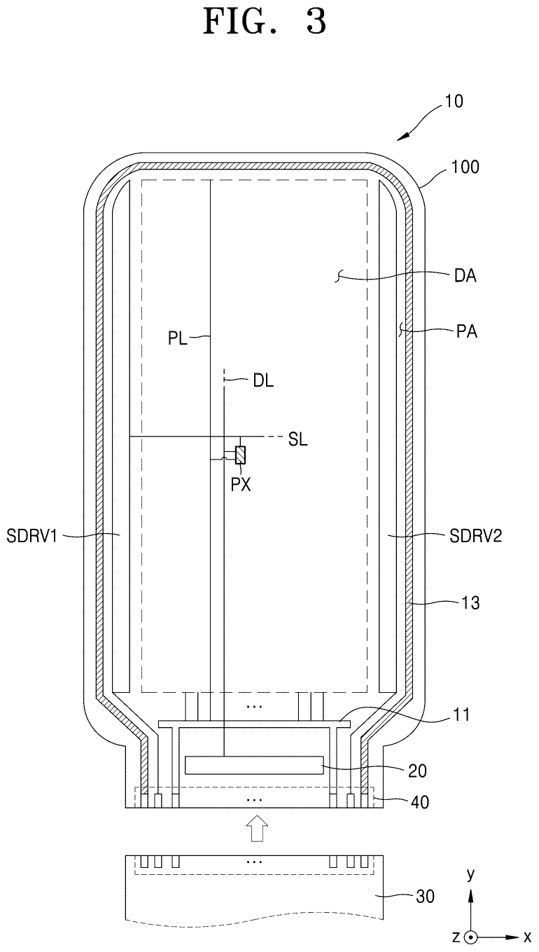

The display panel 10 includes a display area DA and a peripheral area PA outside the display area DA. Because the display panel 10 includes a substrate 100 (see FIG. 3), the substrate 100 may include the display area DA and the peripheral area PA. However, the display area DA and the peripheral area PA may be defined in the substrate 100.

The display area DA is where an image is displayed, and a plurality of sub-pixels may be located in the display area DA. The display area DA may have any of various shapes, such as a circular shape, an elliptical shape, a polygonal shape, or a specific shape. In FIG. 1, for example, the display area DA has a substantially rectangular shape with rounded corners.

The peripheral area PA may be located outside the display area DA. The peripheral area PA may surround at least a part of the display area DA.

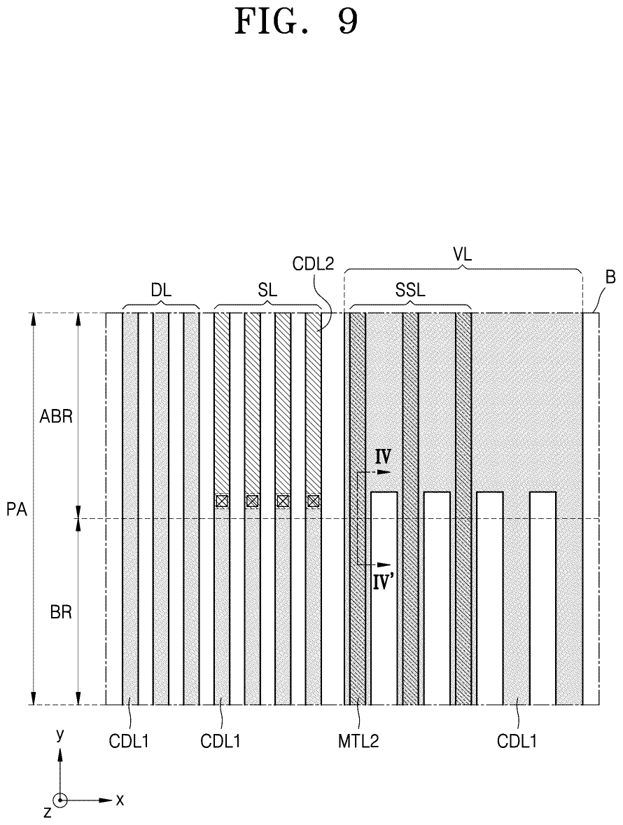

The display panel 10 may include a main area MR, a bendable area BR outside the main area MR, and a sub-area SR located opposite to the main area MR with the bendable area BR therebetween. The main area MR may include the display area DA and a part of the peripheral area PA. The display area DA may occupy most of the main area MR. A portion of the peripheral area PA between the display area DA and the bendable area BR is referred to as a first area ABR, and is described with reference to FIG. 9, et seq., below. The bendable area BR and the sub-area SR may correspond to the remaining part of the peripheral area PA. The display panel 10 can be bent in the bendable area BR as shown in FIG. 2 so that at least a part of the sub-area SR overlaps the main area MR when viewed in a z-axis direction. The sub-area SR may be a non-display area as described below. Since the display panel 10 is bent in the bendable area BR, when the display apparatus 1 is viewed from a front surface (in a −z direction), the non-display area may not be visible, or even when visible, the visible area may be minimized.

A data driver 20 may be disposed in the sub-area SR of the display panel 10. The data driver 20 may include an integrated circuit, such as a driving chip, that drives the display panel 10. The integrated circuit may be, but is not necessarily limited to, a data driving integrated circuit that generates a data signal.

Although the data driver 20 is mounted on the same surface as a display surface of the display area DA, since the display panel 10 is bent in the bendable area BR as described above, the data driver 20 may be located on a rear surface of the main area MR. The data driver 20 may include a plurality of pads.

A printed circuit board 30, etc., may be attached to an end of the sub-area SR of the display panel 10. The printed circuit board 30 may be electrically connected to the data driver 20 through the pads. In an embodiment, the data driver 20 may be disposed on the printed circuit board 30.

Although an organic light-emitting display apparatus according to an embodiment is described as the display apparatus 1, the display apparatus 1 of the present disclosure is not necessarily limited thereto. In other embodiments, the display apparatus 1 of the disclosure may be one of an inorganic light-emitting display apparatus, an inorganic electroluminescent (EL) display apparatus, or a quantum dot light-emitting display apparatus. For example, an emission layer of a display element in the display apparatus 1 may include an organic material, an inorganic material, quantum dots, an organic material and quantum dots, or may include an inorganic material and quantum dots.

FIG. 3 is a schematic plan view of a display panel, according to an embodiment.

Referring to FIG. 3, in an embodiment, the display panel 10 includes the substrate 100. Various elements that constitute the display panel 10 are located on the substrate 100. The substrate 100 may include at least one of glass, a metal, or a polymer resin. Since the display panel 10 can be bent in the bendable area BR (see FIG. 1) as described above, the substrate 100 needs to be flexible or bendable. For example, the substrate 100 may include a polymer resin such as at least one of polyethersulfone, polyacrylate, polyetherimide, polyethylene naphthalate, polyethylene terephthalate, polyphenylene sulfide, polyarylate, polyimide, polycarbonate, or cellulose acetate propionate. Various modifications can be made. For example, the substrate 100 may have a multi-layer structure that includes two layers that include a polymer resin and a barrier layer that includes an inorganic material located between the two layers.

The substrate 100 includes the display area DA and the peripheral area PA outside the display area DA. When an element is described as being located in the display area DA, it means that the element is located in the display area DA of the substrate 100 or overlaps the display area DA of the substrate 100. Likewise, when an element is described as being located in the peripheral area PA, it means that the element is located in the peripheral area PA of the substrate 100 or overlaps the display area DA of the substrate 100.

A plurality of sub-pixels PX may be located in the display area DA. Each of the sub-pixels PX may include a light-emitting diode, such as an organic light-emitting diode (OLED). Each sub-pixel PX may emit, for example, one of red light, green light, blue light, or white light.

Sub-pixel circuits that drive the sub-pixels PX may be connected to a signal line or a voltage line that controls on/off switching and luminance of the light-emitting diode. For example, in FIG. 3, a scan line SL that extends in a first direction, such as an x-direction, and a data line DL that extends in a second direction, such as a y-direction that crosses the first direction, such as the x-direction, are illustrated as signal lines, and a driving voltage line PL is illustrated as a voltage line.

The peripheral area PA may be a non-display area where no image is displayed. The peripheral area PA may entirely surround the display area DA. The peripheral area PA includes outer circuits that drive the sub-pixels PX. For example, the peripheral area PA may include a first scan driver SDRV1, a second scan driver SDRV2, a pad unit 40, a driving voltage supply line 11, and a common voltage supply line 13.

The first scan driver SDRV1 may transmit a scan signal to each of the sub-pixel circuits that drive the sub-pixels PX through the scan line SL. The second scan driver SDRV2 may be located opposite to the first scan driver SDRV1 with the display area DA therebetween and may extend substantially parallel to the first scan driver SDRV1. Some of the sub-pixel circuits in the display area DA may be electrically connected to the first scan driver SDRV1 and the rest may be electrically connected to the second scan driver DRV2.

The pad unit 40 may be disposed on a side of the substrate 100. The pad unit 40 may be exposed without being covered by an insulating layer and may be connected to the printed circuit board 30.

A controller may be disposed on the printed circuit board 30. The controller may generate a control signal that is transmitted to the first scan driver SDRV1 and the second scan driver SDRV2. In addition, the controller may transmit a driving voltage ELVDD to the driving voltage supply line 11 and a common voltage ELVSS to the common voltage supply line 13. The driving voltage ELVDD may be transmitted to the sub-pixel circuits of the sub-pixels PX through the driving voltage line PL, which is connected to the driving voltage supply line 11, and the common voltage ELVSS may be transmitted to a counter electrode of the light-emitting diode, which is connected to the common voltage supply line 13. The driving voltage supply line 11 may be located below the display area DA and may extend in the first direction, such as the x-direction. The common voltage supply line 13 may have a loop shape with an open side that partially surrounds the display area DA.

The controller may generate a data signal, and the generated data signal may be transmitted to the data line DL through the data driver 20. The data signal may be sequentially transmitted to sub-pixels PX located in the same column through data lines DL that extend in the second direction, such as the y-direction. In addition, the controller may generate a touch driving signal transmitted to sensor electrodes of a touch sensor layer.

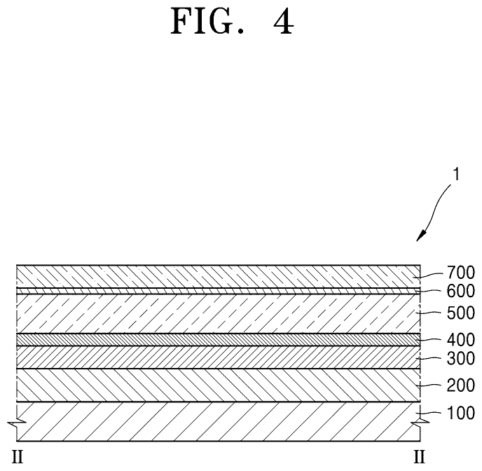

FIG. 4 is a schematic cross-sectional view of a display apparatus, taken along line II-II′ of FIG. 1, according to an embodiment.

Referring to FIG. 4, in an embodiment, the display apparatus includes a display layer 200 disposed on the substrate 100 and that forms the display area DA. The display layer 200 may include a plurality of sub-pixels that each include a light-emitting diode and that provide an image.

An encapsulation layer 300 may covers the display layer 200. The encapsulation layer 300 may protects the display layer 200 from external moisture or oxygen, and a touch sensor layer 400 may be disposed on the encapsulation layer 300.

The touch sensor layer 400 may include a plurality of conductive sensor electrodes. For example, the touch sensor layer 400 may be a capacitive layer. The touch sensor layer 400 may output, by using a capacitance change that occurs when an object, such as a user's hand, approaches or touches a surface of the touch sensor layer 400, coordinates of a location where the object approaches or touches.

An optical functional layer 500 may be disposed on the touch sensor layer 400. The optical functional layer 500 may include an anti-reflection functional layer. The anti-reflection functional layer may include a phase retarder and a polarizer, or may include a black matrix and a color filter.

A cover window 700 may be disposed on the optical functional layer 500 with an adhesive layer 600 interposed therebetween. The adhesive layer 600 may include a transparent optically clear adhesive (OCA).

The cover window 700 may be flexible. For example, the cover window 700 may include a plastic such as polyimide or an ultra-thin glass.

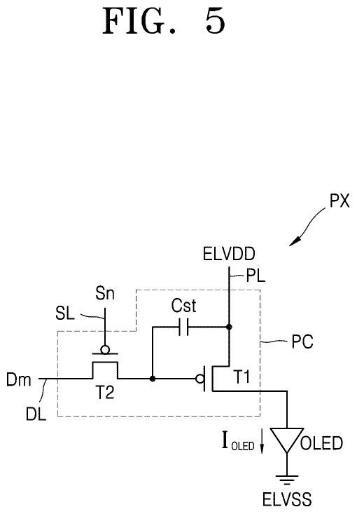

FIG. 5 is an equivalent circuit diagram of a light-emitting diode of a display apparatus and a sub-pixel circuit electrically connected to the light-emitting diode, according to an embodiment.

Referring to FIG. 5, in an embodiment, a sub-pixel circuit PC may be connected to a light-emitting diode, such as an organic light-emitting diode OLED, so that sub-pixels PX can emit light. The sub-pixel circuit PC includes a driving thin-film transistor T1, a switching thin-film transistor T2, and a storage capacitor Cst. The switching thin-film transistor T2 is connected to a scan line GL and a data line DL and transmits a data signal Dm input through the data line DL to the driving thin-film transistor T1 according to a scan signal Sn received through the scan line GL.

The storage capacitor Cst is connected to the switching thin-film transistor T2 and a driving voltage line PL and stores a voltage that corresponds to a difference between a voltage received from the switching thin-film transistor T2 and a driving voltage ELVDD received from the driving voltage line PL.

The driving thin-film transistor T1 may be connected to the driving voltage line PL and the storage capacitor Cst and may control a driving current I_{OLED} that flows from the driving voltage line PL to the organic light-emitting diode OLED in response to a value of the voltage stored in the storage capacitor Cst. The organic light-emitting diode OLED may emit light that has a luminance due to the driving current I_{OLED}.

The number of thin-film transistors and storage capacitors and a circuit design of the sub-pixel circuit PC are not necessarily limited to those of FIG. 5, and can be modified in various ways.

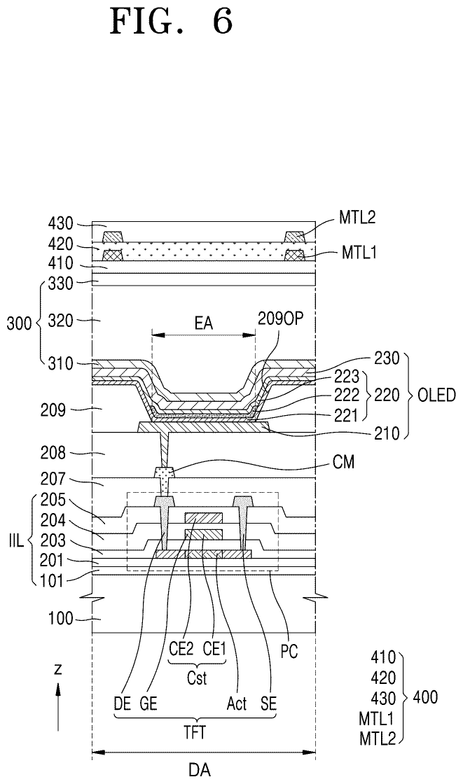

FIG. 6 is a schematic cross-sectional view of a portion of a display area of a display apparatus, according to an embodiment.

Referring to FIG. 6, in an embodiment, the organic light-emitting diode OLED and the sub-pixel circuit PC electrically connected to the organic light-emitting diode OLED may be located in the display area DA of the substrate 100.

A buffer layer 201 may be located on the substrate 100 and reduces or blocks penetration of foreign materials, moisture, or external air from the bottom of the substrate 100 and planarizes the substrate 100. The buffer layer 201 may include an inorganic material such as an oxide or a nitride, an organic material, or an organic/inorganic composite material, and may have a single or multi-layer structure that includes an inorganic material and an organic material.

A barrier layer 101 may be further provided between the substrate 100 and the buffer layer 201 to block penetration of external air. In some embodiments, the barrier layer 101 includes silicon oxide or silicon nitride.

The sub-pixel circuit PC may include a thin-film transistor TFT and a storage capacitor Cst and may be disposed on the buffer layer 201. The thin-film transistor TFT may include a semiconductor layer Act, a gate electrode GE, a drain electrode DE, and a source electrode SE.

The semiconductor layer Act may be disposed on the buffer layer 201 and, in an embodiment, may include polysilicon. In an embodiment, the semiconductor layer Act may include amorphous silicon. In an embodiment, the semiconductor layer Act may include an oxide of at least one of indium (In), gallium (Ga), stannum (Sn), zirconium (Zr), vanadium (V), hafnium (Hf), cadmium (Cd), germanium (Ge), chromium (Cr), titanium (Ti), or zinc (Zn). The semiconductor layer Act may include a channel region, and a source region and a drain region doped with impurities.

A first gate insulating layer 203 may be disposed on the buffer layer 201 and cover the semiconductor layer Act. The first gate insulating layer 203 may include an inorganic insulating material such as at least one of silicon oxide, silicon nitride, silicon oxynitride, aluminum oxide, titanium oxide, tantalum oxide, hafnium oxide, or zinc oxide. The first gate insulating layer 203 may have a single or multi-layer structure that includes the inorganic insulating material.

The gate electrode GE may be disposed on the first gate insulating layer 203 and overlap the semiconductor layer Act. The gate electrode GE may include at least one of molybdenum (Mo), aluminum (Al), copper (Cu), or titanium (Ti) and may have a single or multi-layer structure. For example, the gate electrode GE may have a single-layer structure that includes Mo.

A second gate insulating layer 204 may be disposed on the first gate insulating layer 203 and cover the gate electrode GE. The second gate insulating layer 204 may include an inorganic insulating material such as at least one of silicon oxide, silicon nitride, silicon oxynitride, aluminum oxide, titanium oxide, tantalum oxide, hafnium oxide, or zinc oxide. The second gate insulating layer 204 may have a single or multi-layer structure that includes the inorganic insulating material.

A second capacitor electrode CE2 of the storage capacitor Cst may be located disposed on the second gate insulating layer 204. The second capacitor electrode CE2 may overlap the gate electrode GE. The gate electrode GE and the second capacitor electrode CE2 that overlap each other with the second gate insulating layer 204 therebetween may constitute the storage capacitor Cst. For example, the gate electrode GE may function as a first capacitor electrode CE1 of the storage capacitor Cst.

The second capacitor electrode CE2 may include one or more of aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may have a single or multi-layer structure that includes the above materials.

An interlayer insulating layer 205 may be disposed on the second gate insulating layer 204 and cover the second capacitor electrode CE2. The interlayer insulating layer 205 may include an inorganic insulating material, such as at least one of silicon oxide, silicon nitride, silicon oxynitride, aluminum oxide, titanium oxide, tantalum oxide, hafnium oxide, or zinc oxide. The interlayer insulating layer 205 may have a single or multi-layer structure that includes the above inorganic insulating materials.

The barrier layer 101, the buffer layer 201, the first gate insulating layer 203, the second gate insulating layer 204, and the interlayer insulating layer 205 may be referred to as an inorganic insulating layer IIL.

The source electrode SE and the drain electrode DE may be disposed on the interlayer insulating layer 205. The source electrode SE and the drain electrode DE may each include a conductive material that includes at least one of molybdenum (Mo), aluminum (Al), copper (Cu), or titanium (Ti), and may have a single or multi-layer structure that includes the above materials. For example, the source electrode SE and the drain electrode DE may each have a multi-layer structure that includes Ti/Al/Ti. In some embodiments, the source electrode SE or the drain electrode DE may be omitted. For example, in some embodiments, adjacent thin-film transistors TFT may share the source region or the drain region of the semiconductor layer Act, and the source region or the drain region may function as the source electrode SE or the drain electrode DE.

A first organic insulating layer 207 and a second organic insulating layer 208 may be sequentially disposed on the interlayer insulating layer 205 and cover the source electrode SE and the drain electrode DE. The second organic insulating layer 208 may have a flat top surface so that a sub-pixel electrode 210 disposed on the second organic insulating layer 208 is flat.

The first organic insulating layer 207 and the second organic insulating layer 208 each include an organic material. The first organic insulating layer 207 and the second organic insulating layer 208 may each include an organic insulating material such as at least one of benzocyclobutene (BCB), polyimide, hexamethyldisiloxane (HMDSO), a general-purpose polymer such as polymethyl methacrylate (PMMA) or polystyrene (PS), a polymer derivative having a phenol-based group, an acrylic polymer, an imide-based polymer, an aryl ether-based polymer, an amide-based polymer, a fluorinated polymer, a p-xylene-based polymer, or a vinyl alcohol-based polymer. When the first organic insulating layer 207 and the second organic insulating layer 208 are formed, a layer may be formed and then chemical mechanical polishing may be performed on a top surface of the layer to provide a flat top surface.

A connection electrode CM may be disposed on the first organic insulating layer 207. The first organic insulating layer 207 may include a contact hole through which one of the source electrode SE or the drain electrode DE of the thin-film transistor TFT is exposed, and the connection electrode CM may contact one of the source electrode SE or the drain electrode DE through the contact hole and may be electrically connected to the thin-film transistor TFT.

The connection electrode CM may include a conductive material that includes at least one of molybdenum (Mo), aluminum (Al), copper (Cu), or titanium (Ti), and may have a single or multi-layer structure that includes the above materials.

The sub-pixel electrode 210 may be disposed on the second organic insulating layer 208. The second organic insulating layer 208 may have a contact hole through which the connection electrode CM is exposed, and the sub-pixel electrode 210 may contact the connection electrode CM through the contact hole and may be electrically connected to the thin-film transistor TFT.

The sub-pixel electrode 210 may include a conductive oxide such as at least one of indium tin oxide (ITO), indium zinc oxide (IZO), zinc oxide (ZnO), indium oxide (In₂O₃), indium gallium oxide (IGO), or aluminum zinc oxide (AZO). The sub-pixel electrode 210 may include a reflective film that includes one or more of silver (Ag), magnesium (Mg), aluminum (Al), platinum (Pt), palladium (Pd), gold (Au), nickel (Ni), neodymium (Nd), iridium (Ir), chromium (Cr), or a compound thereof. For example, the sub-pixel electrode 210 may have a structure that includes films formed of one or more of ITO, IZO, ZnO, or In₂O₃ over/under the reflective film. For example, the sub-pixel electrode 210 may have a stacked structure that includes ITO/Ag/ITO.

A bank layer 209 may be disposed on the second organic insulating layer 208 and cover an edge of the sub-pixel electrode 210 and may include an opening 209OP through which a central portion of the sub-pixel electrode 210 is exposed. A size and a shape of an emission area EA of the organic light-emitting diode OLED, that is, a sub-pixel, may be defined by the opening 209OP.

The bank layer 209 may increase a distance between the edge of the sub-pixel electrode 210 and a counter electrode 230 disposed on the sub-pixel electrode 210 and prevent an arc, etc., from occurring on the edge of the sub-pixel electrode 210. The bank layer 209 may be formed of an organic insulating material, such as one of polyimide, polyamide, acrylic resin, benzocyclobutene, hexamethyldisiloxane (HMDSO), or phenolic resin, by using spin coating, etc.

The bank layer 209 may be black. The bank layer 209 may include a light-blocking material that is black. The light-blocking material may include at least one of carbon black, carbon nanotubes, a resin or paste that includes a black dye, metal particles, such as nickel (Ni), aluminum (Al), molybdenum (Mo), or an alloy thereof, metal oxide particles, such as chromium oxide, or metal nitride particles, such as chromium nitride. When the bank layer 209 includes a light-blocking material, the reflection of external light due to metal structures under the bank layer 209 may be reduced.

An intermediate layer 220 may be disposed on the bank layer 209 and the sub-pixel electrode 210 and include an emission layer 222, a first functional layer 221, and a second functional layer 223. The emission layer 222 corresponds to the sub-pixel electrode 210 and is located inside the opening 209OP of the bank layer 209. The emission layer 222 may include a high molecular weight material or a low molecular weight material, and may emit one of red light, green light, blue light, or white light.

The first functional layer 221 and the second functional layer 223 may be respectively disposed under and over the emission layer 222. In an embodiment, the emission layer 222 may be patterned and disposed for each sub-pixel, while the first functional layer 221 and the second functional layer 223 may be integrally disposed over the entire display area DA.

The first functional layer 221 may have a single or multi-layer structure. For example, when the first functional layer 221 is formed of a high molecular weight material, the first functional layer 221 may include a hole transport layer (HTL) that has a single-layer structure and may be formed of poly-(3,4)-ethylene-dihydroxythiophene (PEDOT) or polyaniline (PANI). When the first functional layer 221 is formed of a low molecular weight material, the first functional layer 221 may include a hole injection layer (HIL) and an HTL.

The second functional layer 223 may be optional. For example, when each of the first functional layer 221 and the emission layer 222 is formed of a high molecular weight material, the second functional layer 223 may be formed. The second functional layer 223 may have a single or multi-layer structure. The second functional layer 223 may include an electron transport layer (ETL) and/or an electron injection layer (EIL). In some embodiments, at least one of the HIL, the HTL, the ETL, and the EIL may be omitted.

The counter electrode 230 may be formed of a conductive material that has a relatively low work function. For example, in an embodiment, the counter electrode 230 may include a (semi-)transparent layer that includes at least one of silver (Ag), magnesium (Mg), aluminum (Al), nickel (Ni), chromium (Cr), lithium (Li), calcium (Ca), or an alloy thereof. In an embodiment, the counter electrode 230 may further include a layer formed of one or more of ITO, IZO, ZnO, or In203 on the (semi-)transparent layer. In an embodiment, the counter electrode 230 may include silver (Ag) and magnesium (Mg). A structure in which the sub-pixel electrode 210, the intermediate layer 220, and the counter electrode 230 are sequentially stacked may form the organic light-emitting diode OLED.

In an embodiment, a capping layer may be disposed on the organic light-emitting diode OLED. The capping layer may increase the luminous efficiency of the organic light-emitting element OLED according to the principle of constructive interference. The capping layer may be an organic capping layer that includes an organic material, an inorganic capping layer that includes an inorganic material, or a composite capping layer that includes an organic material and an inorganic material.

The encapsulation layer 300 may be disposed on the organic light-emitting diode OLED. In an embodiment, the encapsulation layer 300 may include at least one inorganic encapsulation layer and at least one organic encapsulation layer. For example, the encapsulation layer 300 may include first and second inorganic encapsulation layers 310 and 330, and an organic encapsulation layer 320 interposed between the first and second inorganic encapsulation layers 310 and 330.

The first and second inorganic encapsulation layers 310 and 330 may each include at least one inorganic insulating material. The inorganic insulating material may be one or more of aluminum oxide, titanium oxide, tantalum oxide, hafnium oxide, zinc oxide, silicon oxide, silicon nitride, and/or silicon oxynitride. The first and second inorganic encapsulation layers 310 and 330 may be formed by using chemical vapor deposition.

The organic encapsulation layer 320 may include an organic insulating material. The organic insulating material may be one or more of polyethylene terephthalate, polyethylene naphthalate, polycarbonate, polyimide, polyethylene polyoxymethylene, polyarylate, hexamethyldisiloxane, an acrylic resin, such as polymethyl methacrylate or polyacrylic acid, or a combination thereof.

The encapsulation layer 300 may cover the entire display area DA and may extend into the peripheral area PA and cover at least a part of the peripheral area PA.

The touch sensor layer 400 may have a multi-layer structure. The touch sensor layer 400 includes a sensor electrode, a detection signal line (trace line) connected to the sensor electrode, and at least one insulating layer. The touch sensor layer 400 may detect an external input by using, for example, a capacitive method. As described above, an operation method of the touch sensor layer 400 is not particularly limited, and in some embodiments, the touch sensor layer 400 can detect an external input by using an electromagnetic induction method or a pressure sensing method.

The touch sensor layer 400 may include a first touch insulating layer 410, a first touch conductive layer MTL1, a second touch insulating layer 420, a second touch conductive layer MTL2, and a third touch insulating layer 430.

The first touch insulating layer 410 may be disposed directly on the encapsulation layer 300. The first touch insulating layer 410 may include an inorganic material or an organic material and may have a single or multi-layer structure. The organic material may include at least one of an acrylic resin, a methacrylic resin, polyisoprene, a vinyl resin, an epoxy resin, a urethane resin, a cellulose resin, or a perylene resin. The inorganic material may include at least one of silicon nitride, aluminum nitride, zirconium nitride, titanium nitride, hafnium nitride, tantalum nitride, silicon oxide, aluminum oxide, titanium oxide, tin oxide, cerium oxide, or silicon oxynitride.

The first touch insulating layer 410 may prevent damage to the encapsulation layer 300 and may block an interference signal that can occur when the touch sensor layer 400 is driven.

The first touch conductive layer MTL1 and the second touch conductive layer MTL2 may each include a metal layer or a transparent conductive layer. The metal layer may include at least one of molybdenum (Mo), silver (Ag), titanium (Ti), copper (Cu), aluminum (Al), or an alloy thereof. The transparent conductive layer may include a transparent conductive oxide, such as one of indium tin oxide (ITO), indium zinc oxide (IZO), zinc oxide (ZnO), or indium tin zinc oxide (ITZO). Each of the first touch conductive layer MTL1 and the second touch conductive layer MTL2 may have a single or multi-layer structure. For example, the first touch conductive layer MTL1 and the second touch conductive layer MTL2 may each have a three-layer structure that includes Ti/Al/Ti.

The first touch conductive layer MTL1 and the second touch conductive layer MTL2 may each include a plurality of patterns. The first touch conductive layer MTL1 may include first conductive patterns, and the second touch conductive layer MTL2 may include second conductive patterns. The first conductive patterns and the second conductive patterns may form a sensor electrode.

The first touch conductive layer MTL1 and the second touch conductive layer MTL2 may be electrically connected to each other through a contact hole. In an embodiment, the first touch conductive layer MTL1 and the second touch conductive layer MTL2 may each have a mesh structure through which light emitted from the organic light-emitting diode OLED can pass. For example, the first touch conductive layer MTL1 and the second touch conductive layer MTL2 may not overlap the emission area EA.

The second touch insulating layer 420 may include an inorganic material or an organic material. The organic material may include at least one of an acrylic resin, a methacrylic resin, polyisoprene, a vinyl resin, an epoxy resin, a urethane resin, a cellulose resin, or a perylene resin. The inorganic material may include at least one of silicon nitride, aluminum nitride, zirconium nitride, titanium nitride, hafnium nitride, tantalum nitride, silicon oxide, aluminum oxide, titanium oxide, tin oxide, cerium oxide, or silicon oxynitride.

The third touch insulating layer 430 may be disposed on the second touch conductive layer MTL2. The third touch insulating layer 430 may have a single or multi-layer structure. The third touch insulating layer 430 may include an organic material, an inorganic material, or a composite material. The inorganic material may include at least one of silicon nitride, aluminum nitride, zirconium nitride, titanium nitride, hafnium nitride, tantalum nitride, silicon oxide, aluminum oxide, titanium oxide, tin oxide, cerium oxide, or silicon oxynitride. The organic material may include at least one of an acrylic resin, a methacrylic resin, polyisoprene, a vinyl resin, an epoxy resin, a urethane resin, a cellulose resin, or a perylene resin.

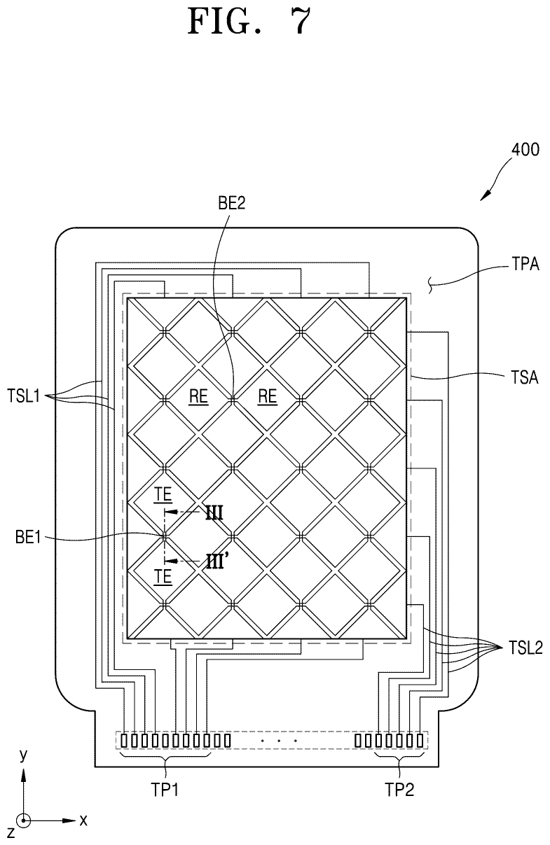

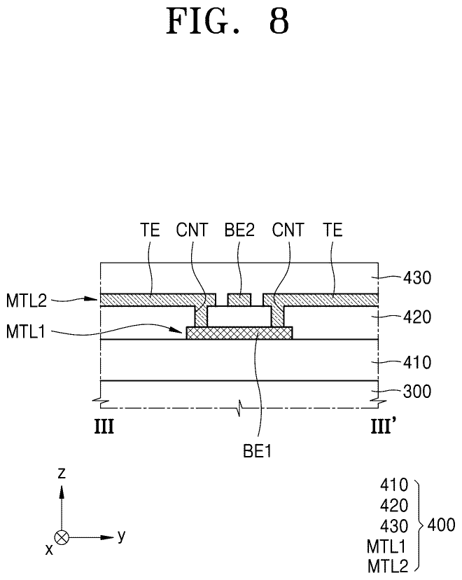

FIG. 7 is a plan view of a touch sensor layer of a display apparatus, according to an embodiment. FIG. 8 is a schematic cross-sectional view of a touch sensor layer, taken along line III-III′ of FIG. 7, according to an embodiment.

Referring to FIG. 7, in an embodiment, the touch sensor layer 400 may include a touch sensor area TSA that detects a user's touch and a touch peripheral area TPA located outside the touch sensor area TSA. The touch sensor area TSA may overlap the display area DA of the substrate 100, and the touch peripheral area TPA may overlap the peripheral area PA of the substrate 100.

For convenience of illustration, FIG. 7 shows only sensor electrodes in the first touch conductive layer MTL1 (see FIG. 6) and the second touch conductive layer MTL2 (see FIG. 6), sensor wirings connected to the sensor electrodes, and sensor pads of the touch sensor layer 400. The sensor electrodes may include a driving electrode TE and a detection electrode RE. The sensor wirings may include a first detection signal line TSL1 and a second detection signal line TSL2. The sensor pads may include a first detection signal pad TP1 and a second detection signal pad TP2.

Each of the driving electrode TE and the detection electrode RE may have, but is not necessarily limited to, a rhombus planar shape. Although FIG. 7 shows the sensor electrodes as having a rhombus planar shape for convenience of illustration, each of the driving electrode TE, the detection electrode RE, a first touch connection electrode BE1, and a second touch connection electrode BE2 may have a mesh structure in a plan view. The detection electrodes RE may be arranged in the first direction, such as the x-direction and extend in the second direction, such as the y-direction, and may be electrically connected. The driving electrodes TE may be arranged in the second direction, such as the y-direction and extend in the first direction, such as the x-direction, and may be electrically connected. The driving electrodes TE and the detection electrodes RE may be spaced apart from each other. In intersection areas of the detection electrodes RE and the driving electrodes TE, the driving electrodes TE adjacent to each other in the second direction, such as the y-direction, may be connected to each other through the first touch connection electrode BE1, and the detection electrodes RE adjacent to each other in the first direction, such as the x-direction, may be connected to each other through the second touch connection electrode BE2.

In an embodiment, as shown in FIG. 8, the driving electrode TE, the detection electrode RE, and the second touch connection electrode BE2 may be part of the second touch conductive layer MTL2, and the first touch connection electrode BE1 may be part of the first touch conductive layer MTL1. In another embodiment, the driving electrode TE, the detection electrode RE, and the second touch connection electrode BE2 may be part the first touch conductive layer MTL1, and the first touch connection electrode BE1 may be part of the second touch conductive layer MTL2.

For example, as shown in FIG. 8, in an embodiment, the first touch connection electrode BE1 may be disposed on the first touch insulating layer 410, and the driving electrode TE and the second touch connection electrode BE2 may be disposed on the second touch insulating layer 420. Adjacent driving electrodes TE may be electrically connected to each other through the first touch connection electrode BE1 and may be connected to the first touch connection electrode BE1 through a contact hole CNT that passes through the second touch insulating layer 420.

The first detection signal line TSL1 and the second detection signal line TSL2, which are the sensor wirings, may be located in the touch peripheral area TPA. The driving electrodes TE of the touch sensor area TSA may be connected to the first detection signal lines TSL1. The first detection signal lines TSL1 may be connected to the first detection signal pads TP1. The driving electrodes TE may receive a touch driving signal through the first detection signal lines TSL1. One end of the detection electrodes RE may be connected to the second detection signal line TSL2. The second detection signal lines TSL2 may be connected to the second detection signal pads TP2. In addition, some of the first detection signal lines TSL1 and the second detection signal lines TSL2 may be ground wirings not connected to the driving electrode TE and the detection electrode RE.

The first detection signal pads TP1 and the second detection signal pads TP2 may be disposed on a lower side of the display panel 10. In an embodiment, the printed circuit board 30 may be disposed on the first detection signal pads TP1 and the second detection signal pads TP2.

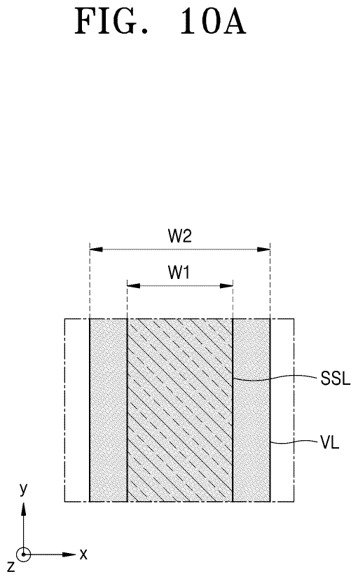

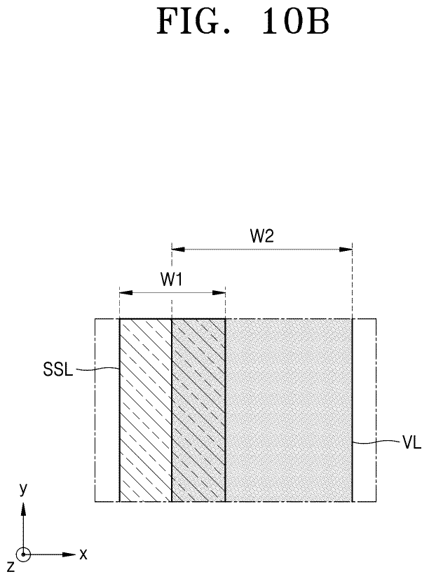

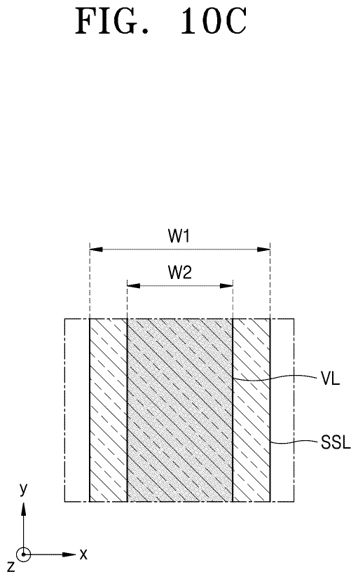

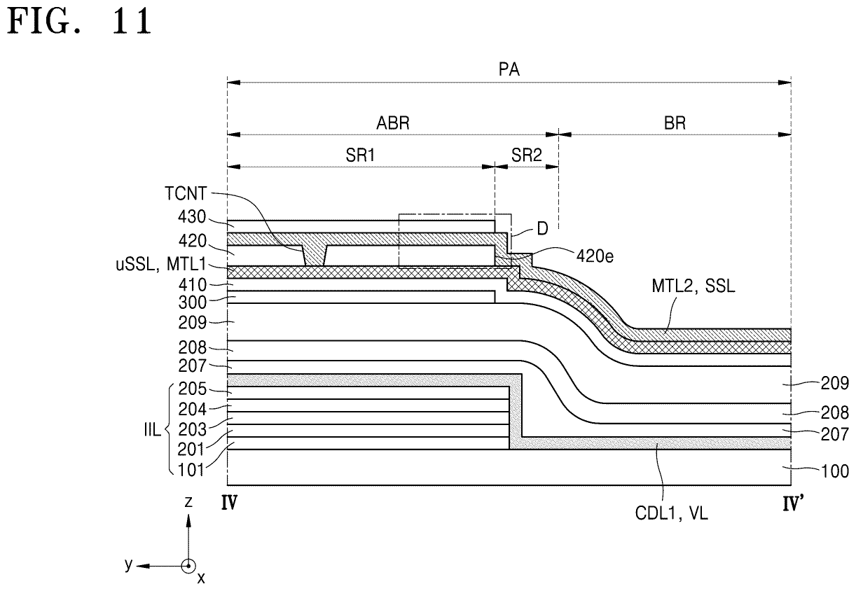

FIG. 9 is an enlarged plan view of a portion B of a peripheral area of a display apparatus of FIG. 1, according to an embodiment. FIGS. 10A to 10C are schematic plan views of a power supply wiring and a sensor wiring, according to an embodiment. FIG. 11 is a cross-sectional view of a sensor wiring, taken along line IV-IV′ of FIG. 9.

Referring to FIG. 9, in an embodiment, a first area ABR and the bendable area BR may extend from the display area DA (see FIG. 1). As shown in FIG. 1, the first area ABR may be located in the peripheral area PA and between the display area DA and the bendable area BR. The first area ABR may be a portion of the peripheral area PA adjacent to the bendable area BR.

In the first area ABR and the bendable area BR, data lines DL, signal lines SL, power supply wirings VL, and sensor wirings SSL that extend from the display area DA may be located. The data lines DL, the signal lines SL, the power supply wirings VL, and the sensor wirings SSL may extend, for example, in the second direction, such as the y-direction.

For example, the data lines DL, the signal lines SL, and the power supply wirings VL may be connected to a sub-pixel circuit of the sub-pixel PX (see FIG. 3) in the display area DA. For example, the power supply wiring VL may correspond to the driving voltage line PL (see FIG. 3) that transmits a driving voltage to the sub-pixel circuit, or to a common voltage line that transmits a common voltage to an organic light-emitting diode. In addition, the sensor wirings SSL may each be connected to the driving electrode TE (see FIG. 7) or the detection electrode RE (see FIG. 7) in the display area DA. The sensor wirings SSL may include the first detection signal line TSL1 (see FIG. 7) and the second detection signal line TSL2 (see FIG. 7) in the peripheral area PA.

Although FIG. 9 shows one side portion, such as a right portion, of the first area ABR and the bendable area BR, the same wirings may be located in the other side portion, such as a left portion, of the first area ABR and the bendable area BR.

The data lines DL may be spaced apart from each other. The signal lines SL may be spaced apart from each other. The sensor wirings SSL may be spaced apart from each other. In an embodiment, the power supply wiring VL may branch into a plurality of portions in the first area ABR and may be spaced apart from each other in the bendable area BR.

In an embodiment, the power supply wirings VL and the sensor wirings SSL may be disposed in different layers. In an embodiment, the power supply wirings VL and the sensor wirings SSL may overlap each other in a third direction, such as a z-direction that crosses the first direction and the second direction, in the first area ABR. The power supply wirings VL and the sensor wirings SSL may overlap each other in the third direction, such as the z-direction, in the bendable area BR. The power supply wirings VL and the sensor wirings SSL may extend parallel to each other in the second direction, such as the y-direction.

In an embodiment, the sensor wirings SSL and the power supply wirings VL may overlap each other in the third direction, such as the z-direction, in a one-to-one manner. In an embodiment, the sensor wirings SSL and the power supply wirings VL may overlap each other in the third direction, such as the z-direction, in a one-to-many manner. For example, one power supply wiring VL and a plurality of sensor wirings SSL may overlap each other, or one sensor wiring SSL and a plurality of power supply wirings VL may overlap each other.

When the power supply wirings VL and the sensor wirings SSL overlap each other in the third direction, such as the z-direction, in the first area ABR and the bendable area BR, an area that corresponds to a width of the sensor wirings SSL may be secured compared to a case in which the power supply wirings VL and the sensor wirings SSL are disposed in the same layer and do not overlap each other in the third direction, such as the z-direction. Accordingly, in the first area ABR and the bendable area BR, widths of the data lines DL, the signal lines SL, the power supply wirings VL, and the sensor wirings SSL may increase, and the resistance of the wirings may decrease. In addition, because an interval between the wirings is ensured, a short-circuit between the wirings can be prevented.

Referring to FIGS. 10A to 10C, in some embodiments, the power supply wiring VL and the sensor wiring SSL may each have a predetermined width and may overlap each other in the third direction, such as the z-direction. A width of one of the power supply wiring VL or the sensor wiring SSL may be greater than a width of the other. As shown in FIG. 10A, a width W1 of the sensor wiring SSL may be less than a width W2 of the power supply wiring VL. The sensor wiring SSL may completely overlaps the power supply wiring VL in the third direction, such as the z-direction. As shown in FIG. 10B, the width W1 of the sensor wiring SSL may be less than the width W2 of the power supply wiring VL. The sensor wiring SSL may protrude from one side of the power supply wiring VL so that a part of the sensor wiring SSL overlaps the power supply wiring VL in the third direction, such as the z-direction, and the remaining part does not overlap the power supply wiring VL. However, as shown in FIG. 10C, the width W1 of the sensor wiring SSL may be greater than the width W2 of the power supply wiring VL. The power supply wiring VL may completely overlap the sensor wiring SSL in the third direction, such as the z-direction. Both sides of the sensor wiring SSL may protrude from the power supply wiring VL so that a part of the sensor wiring SSL overlaps the power supply wiring VL in the third direction, such as the z-direction, and the remaining part does not overlap the power supply wiring VL.

The data lines DL and the power supply wirings VL may include a first metal layer CDL1 in the first area ABR and the bendable area BR. The first metal layer CDL1 may include the same material as that of the source electrode SE or the drain electrode DE of the thin-film transistor TFT described with reference to FIG. 6. For example, each of the data lines DL and the power supply wirings VL may have a multi-layer structure that includes Ti/Al/Ti.

The signal lines SL may include a second metal layer CDL2 in the first area ABR. The second metal layer CDL2 may include the same material as that of the gate electrode GE of the thin-film transistor TFT described with reference to FIG. 6. The signal lines SL may include the first metal layer CDL1 in the bendable area BR. The signal lines SL may jump from the second metal layer CDL2 to the first metal layer CDL1 through a contact hole in the first area ABR.

The sensor wirings SSL may be the second touch conductive layer MTL2 in the first area ABR and the bendable area BR. In an embodiment, the second touch conductive layer MTL2 may be a second conductive layer. The sensor wirings SSL may include the same material as the sensor electrodes, that is, the driving electrode TE and the detection electrode RE described with reference to FIG. 7. For example, the sensor wirings SSL may have a multi-layer structure that includes Ti/Al/Ti. In an embodiment, when the wirings have a multi-layer structure that includes Ti/Al/Ti in the bendable area BR, reliability may be increased and cracks may not occur when the display panel 10 is bent.

Referring to FIG. 11, in an embodiment, the inorganic insulating layer IIL may be disposed on the substrate 100. The inorganic insulating layer IIL may be disposed in the display area DA and the peripheral area PA. The inorganic insulating layer IIL may include the barrier layer 101, the buffer layer 201, the first gate insulating layer 203, the second gate insulating layer 204, and the interlayer insulating layer 205 that are sequentially stacked. The inorganic insulating layer IIL maybe located in the first area ABR and but not in the bendable area BR. The inorganic insulating layer IIL may have an inclined surface located at a boundary between the first area ABR and the bendable area BR. In an embodiment, the inclined surface of the inorganic insulating layer IIL may extend in the third direction, such as the z-direction, and may be perpendicular to a surface defined by the first direction, such as the x-direction, and the second direction, such as the y-direction.

In the specification, the boundary between the first area ABR and the bendable area BR may include a portion of the first area ABR adjacent to the bendable area BR.

The power supply wiring VL may be disposed on the inorganic insulating layer IIL. The power supply wiring VL may be located in the first area ABR and the bendable area BR, and may be disposed on the inclined surface of the inorganic insulating layer IIL at the boundary between the first area ABR and the bendable area BR.

The first organic insulating layer 207, the second organic insulating layer 208, and the bank layer 209 may be sequentially stacked on the power supply wiring VL. The first organic insulating layer 207, the second organic insulating layer 208, and the bank layer 209 may be located in the first area ABR and the bendable area BR.

The encapsulation layer 300 may be disposed on the bank layer 209. The encapsulation layer 300 may be located in the first area ABR, but not in the bendable area BR.

The first touch insulating layer 410 may be disposed on the encapsulation layer 300. The first touch insulating layer 410 may be located in the first area ABR and the bendable area BR. The first touch insulating layer 410 may be disposed located under a sub-sensor wiring uSSL and protect the sub-sensor wiring SSL. In an embodiment, the first touch insulating layer 410 may be a first insulating layer.

The sub-sensor wiring uSSL may be disposed on the first touch insulating layer 410. The sub-sensor wiring uSSL may be located in the first area ABR. In an embodiment, the sub-sensor wiring uSSL may extend to the bendable area BR. The sub-sensor wiring uSSL may correspond to the first touch conductive layer MTL1. In an embodiment, the first touch conductive layer MTL1 may be a first conductive layer. The sub-sensor wiring uSSL may include the same material as the sensor electrodes, such as the driving electrode TE and the detection electrode RE described with reference to FIG. For example, the sub-sensor wiring uSSL may have a multi-layer structure that includes Ti/Al/Ti. The sub-sensor wiring uSSL may be disposed under the sensor wiring SSL and overlap the sensor wiring SSL in the third direction, such as the z-direction.

The second touch insulating layer 420 may be disposed on the sub-sensor wiring uSSL. The second touch insulating layer 420 may be located in the first area ABR but not in the bendable area BR. With respect to an edge 420e of the second touch insulating layer 420, the first area ABR may include a first sub-area SR1 and a second sub-area SR2. The second touch insulating layer 420 may be located in the first sub-area SR1. The second sub-area SR2 may be closer to the bendable area BR than the first sub-area SR1. The second touch insulating layer 420 may not be located in the second sub-area SR2. In an embodiment, the second touch insulating layer 420 may be a second insulating layer.

The sensor wiring SSL may be disposed on the second touch insulating layer 420 in the first area ABR. The sensor wiring SSL may extend to the bendable area BR. The sensor wiring SSL may directly contact the edge 420e of the second touch insulating layer 420, such as a side surface of the second touch insulating layer 420. In the first sub-area SR1, the sensor wiring SSL may overlap the sub-sensor wiring uSSL in the third direction, such as the z-direction, with the second touch insulating layer 420 interposed therebetween. In the first sub-area SR1, the sensor wiring SSL may contact the sub-sensor wiring uSSL through a contact hole TCNT formed in the second touch insulating layer 420. In the second sub-area SR2 and the bendable area BR, the sensor wiring SSL may be disposed on a top surface of the sub-sensor wiring uSSL. In the second sub-area SR2 and the bendable area BR, the sensor wiring SSL may directly contact the sub-sensor wiring uSSL.

The third touch insulating layer 430 may be disposed on the sensor wiring SSL. The third touch insulating layer 430 may be located in the first area ABR but not the bendable area BR. In an embodiment, the third touch insulating layer 430 may be located in the first sub-area SR1 but not the second sub-area SR2.

A display apparatus according to an embodiment can be flexibly bent in the bendable area BR by arranging the inorganic insulating layer IIL, the encapsulation layer 300, the second touch insulating layer 420, and the third touch insulating layer 430 so as not to extend into the bendable area BR.

A display apparatus according to an embodiment can smooth a stepped structure under the sensor wiring SSL by disposing the sub-sensor wiring uSSL under the sensor wiring SSL and so that the sub-sensor wiring uSSL overlaps the sensor wiring SSL in the third direction, such as the z-direction, in the first area ABR and the bendable area BR.

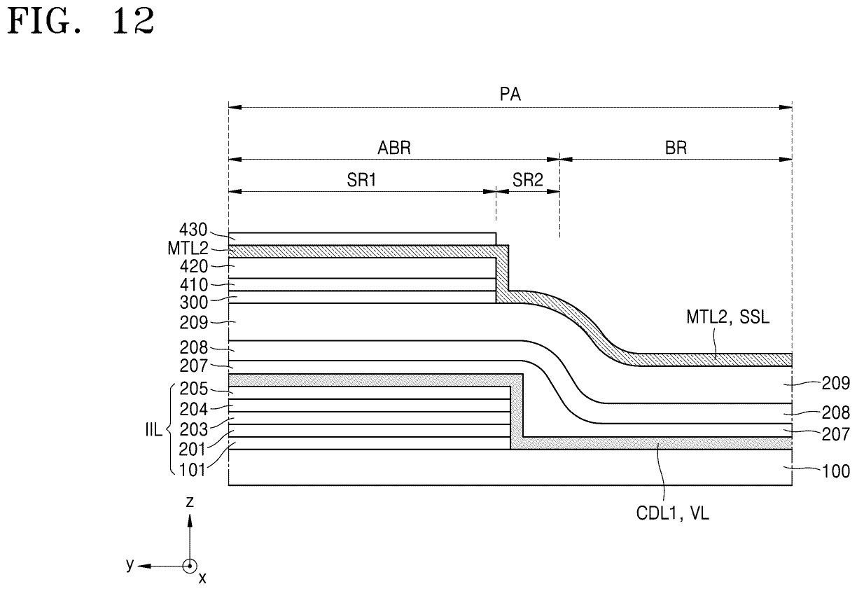

FIG. 12 is a schematic cross-sectional view of a portion of a display apparatus, according to a comparative example.

Referring to FIG. 12, a display apparatus according to a comparative example might not include the sub-sensor wiring uSSL (see FIG. 11) that overlaps the sensor wiring SSL in the third direction, such as the z-direction, in the first area ABR. The first touch insulating layer 410 might not extend into the bendable area BR. For example, a stepped structure in which the encapsulation layer 300, the first touch insulating layer 410, and the second touch insulating layer 420 are stacked, may be formed at a boundary between the first area ABR and the bendable area BR. A residual film of the sensor wiring SSL that passes through the stepped structure may be generated, and thus, there may be a risk of a short-circuit between adjacent sensor wirings SSL.

However, according to an embodiment, because the sub-sensor wiring uSSL that overlaps the sensor wiring SSL in the third direction, such as the z-direction, is included, and the sub-sensor wiring uSSL and the first touch insulating layer 410 are located in the first area ABR and the bendable area BR, a stepped structure of the second touch insulating layer 420 may be formed at a boundary between the first area ABR and the bendable area BR. For example, a step difference under the sensor wiring SSL may be reduced. Accordingly, a risk of a short-circuit between adjacent sensor wirings SSL may be reduced.

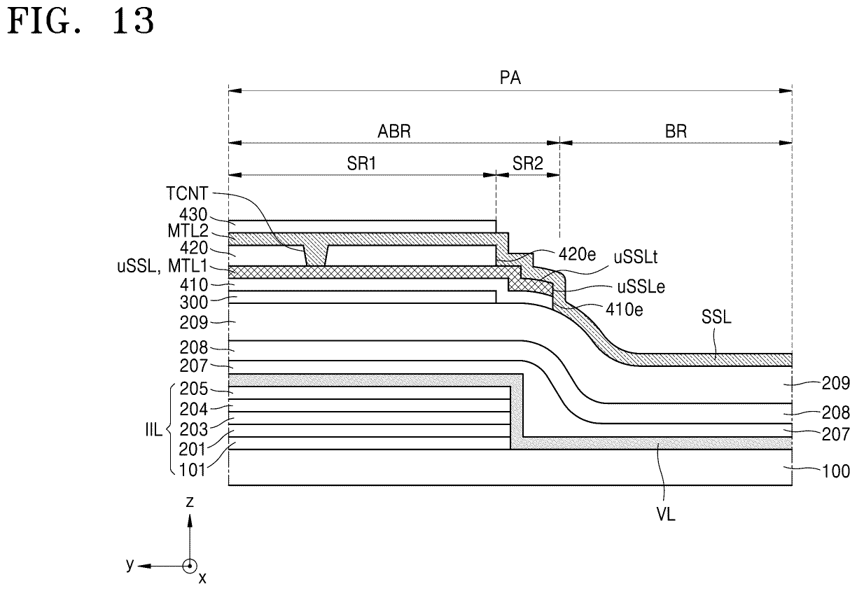

FIG. 13 is a schematic cross-sectional view of a portion of a display apparatus, according to an embodiment. FIG. 13 shows a modification of an embodiment of FIG. 11, and a difference will be mainly described and repeated descriptions of components already described will be omitted.

Referring to FIG. 13, in an embodiment, the sub-sensor wiring uSSL may be disposed in the first area ABR but not in the bendable area BR. The first touch insulating layer 410 may be disposed in the first area ABR but not in the bendable area BR.

In an embodiment, an edge 410e of the first touch insulating layer 410, such as a side surface of the first touch insulating layer 410, may be closer to the bendable area BR than an edge 420e of the second touch insulating layer 420, such as a side surface of the second touch insulating layer 420.

In an embodiment, the sensor wiring SSL may directly contact a top surface uSSLt and a side surface uSSLe of the sub-sensor wiring uSSL. The sensor wiring SSL may directly contact the side surface 410e of the first touch insulating layer 410 and the side surface 420e of the second touch insulating layer 420. In the bendable area BR, the sensor wiring SSL may be disposed on a top surface of an organic insulating layer, such as the bank layer 209.

Because a display apparatus according to an embodiment includes the sub-sensor wiring uSSL that overlaps the sensor wiring SSL in the third direction, such as the z-direction, and is disposed under the sensor wiring SSL in the first area ABR adjacent to the bendable area BR, a stepped structure under the sensor wiring SSL may be smooth. In an embodiment, the second touch insulating layer 420 may be disposed in the first sub-area SR1 but not the second sub-area SR2, but the sub-sensor wiring uSSL and the first touch insulating layer 410 may be disposed in the first sub-area SR1 and the second sub-area SR2. For example, the edge uSSLe of the sub-sensor wiring uSSL and the edge 410e of the first touch insulating layer 410 may be closer to the bendable area BR than the edge 420e of the second touch insulating layer 420. For example, at a boundary between the first area ABR and the bendable area BR, the sensor wiring SSL may sequentially pass through a stepped structure of the second touch insulating layer 420 and a stepped structure of the first touch insulating layer 410, which are spaced apart from each other in the third direction, such as the z-direction. Accordingly, the generation of a residual wiring film due to a stepped structure may be reduced, and the risk of a short-circuit between adjacent sensor wirings SSL may be reduced.

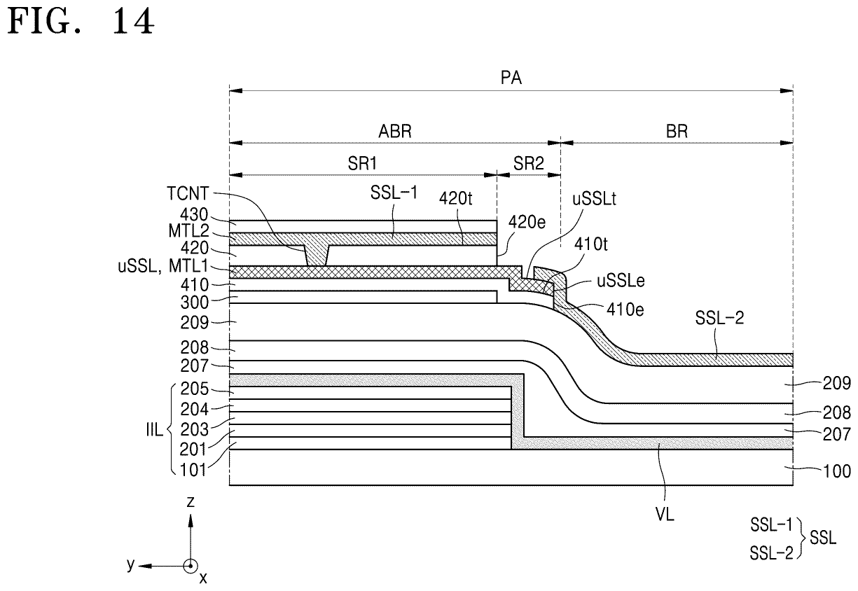

FIG. 14 is a schematic cross-sectional view of a portion of a display apparatus, according to an embodiment. FIG. 14 shows a modification of an embodiment shown in FIG. 13, and differences thereof will be mainly described and a repeated description of components already described will be omitted.

Referring to FIG. 14, in an embodiment, the sensor wiring SSL may include a first wiring portion SSL-1 and a second wiring portion SSL-2. The first wiring portion SSL-1 and the second wiring portion SSL-2 may be spaced apart from each other in the second direction, such as the y-direction. The first wiring portion SSL-1 may be disposed on a top surface 420t of the second touch insulating layer 420. The first wiring portion SSL-1 may be located in the first sub-area SR1. The first wiring portion SSL-1 may directly contact the sub-sensor wiring uSSL through the contact hole TCNT formed in the second touch insulating layer 420.

The second wiring portion SSL-2 may be disposed on the sub-sensor wiring uSSL and the bank layer 209. The second wiring portion SSL-2 may be located in the second sub-area SR2 and the bendable area BR. In the second sub-area SR2, the second wiring portion SSL-2 may directly contact the top surface uSSLt and the side surface uSSLe of the sub-sensor wiring uSSL. In the bendable area BR, the second wiring portion SSL-2 may be disposed on a top surface of an organic insulating layer, such as the bank layer 209. The second wiring portion SSL-2 may be spaced apart from the side surface 420e of the second touch insulating layer 420 in the second direction, such as the y-direction. The first wiring portion SSL-1 and the second wiring portion SSL-2 of the sensor wiring SSL may be electrically connected to each other through the sub-sensor wiring uSSL.

In an embodiment, the first wiring portion SSL-1 and the second wiring portion SSL-2 of the sensor wiring SSL may not cover a part of the side surface 420e of the second touch insulating layer 420 and the top surface uSSLt of the sub-sensor wiring uSSL. For example, the sensor wiring SSL may include the first wiring portion SSL-1 and the second wiring portion SSL-2 that are spaced apart from each other in the second direction, such as the y-direction, and may expose the side surface 420e of the second touch insulating layer 420. The sensor wiring SSL might not be disposed on a stepped structure of the second touch insulating layer 420. Accordingly, the generation of a residual wiring film due to the stepped structure may be further reduced, and the risk of a short-circuit between adjacent sensor wirings SSL may be further reduced.

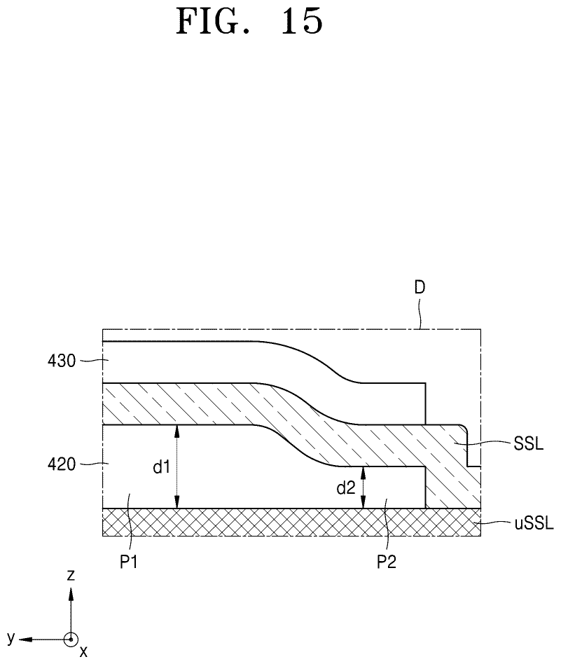

FIG. 15 shows a modification of an embodiment of FIG. 11 and is an enlarged cross-sectional view of a portion D of FIG. 11.

While the second touch insulating layer 420 of FIG. 11 has a substantially uniform thickness, referring to FIG. 15, in some embodiments, the second touch insulating layer 420 may include portions that have different thicknesses.

In an embodiment, the second touch insulating layer 420 may include a first portion P1 and a second portion P2 that have different thicknesses. The second portion P2 of the second touch insulating layer 420 may be closer to the bendable area BR than the first portion P1 of the second touch insulating layer 420. A thickness d2 of the second portion P2 of the second touch insulating layer 420 may be less than a thickness d1 of the first portion P1 of the second touch insulating layer 420. For example, a thickness of the second touch insulating layer 420 may decrease closer to the bendable area BR. For example, because a step difference at the edge 420e of the second touch insulating layer 420 is reduced, the generation of a residual film of the sensor wiring SSL may be further reduced.

In an embodiment, the first portion P1 and the second portion P2 of the second touch insulating layer 420 may be formed by using a halftone mask or a slit mask.

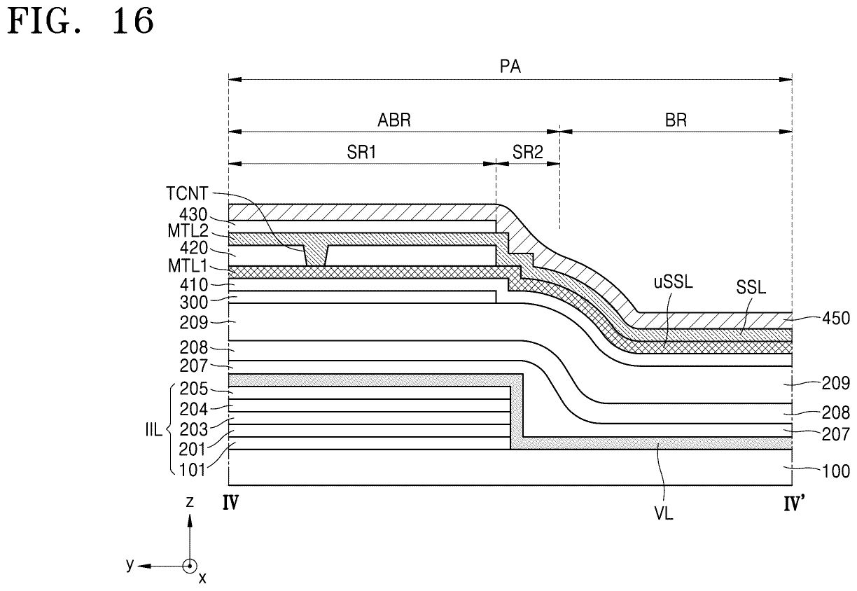

FIG. 16 is a schematic cross-sectional view of a portion of a display apparatus, according to an embodiment. FIG. 16 shows a modification of an embodiment of FIG. 11, and differences thereof will be mainly described and a repeated description of components already described will be omitted.

Referring to FIG. 16, in an embodiment, an organic layer 450 may be further disposed on the third touch insulating layer 430 and the sensor wiring SSL. In an embodiment, the organic layer 450 may be interposed between the touch sensor layer 400 (see FIG. 4) and the optical functional layer 500 (see FIG. 4).

The organic layer 450 may be located in the first area ABR and the bendable area BR. In the first sub-area SR1 of the first area ABR, the organic layer 450 covers the third touch insulating layer 430. In the second sub-area SR2 of the first area ABR and the bendable area BR, the organic layer 450 may cover the sensor wiring SSL. In the bendable area BR, when the organic layer 450 is disposed on the sensor wiring SSL, stress of the sensor wiring SSL during bending may be reduced.

Because a display apparatus according to an embodiment includes a sub-sensor

wiring that overlaps a sensor wiring in a third direction and is disposed under the sensor wiring in a first area between a display area and a bendable area, a stepped structure under the sensor wiring may be smooth and thus, a short-circuit between sensor wirings can be prevented. However, the scope of embodiments of the present disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims.

What is claimed is:

1. A display apparatus, comprising:
a substrate that includes a display area, a peripheral area located outside the display area, a bendable area located in the peripheral area, and a first area located between the display area and the bendable area;
an inorganic insulating layer disposed in the display area and the peripheral area;
a light-emitting diode disposed in the display area;
an encapsulation layer disposed on the light-emitting diode;
a touch sensor layer disposed on the encapsulation layer;
a power supply wiring disposed on the inorganic insulating layer and that extends from the display area to the first area and the bendable area;
a sensor wiring that extends from the display area to the first area and the bendable area and that overlaps the power supply wiring; and
a sub-sensor wiring disposed under the sensor wiring in the first area and that overlaps the sensor wiring.

2. The display apparatus of claim 1, wherein the inorganic insulating layer is disposed in the first area and is not disposed in the bendable area.

3. The display apparatus of claim 1, further comprising an organic insulating layer interposed between the inorganic insulating layer and the light-emitting diode,
wherein the sensor wiring overlaps the power supply wiring with the organic insulating layer interposed therebetween.

4. The display apparatus of claim 3, wherein, in the bendable area, the sensor wiring is disposed on a top surface of the organic insulating layer.

5. The display apparatus of claim 1, wherein the first area comprises a first sub-area and a second sub-area located between the first sub-area and the bendable area,
wherein, in the first sub-area, the sensor wiring overlaps the sub-sensor wiring with an insulating layer interposed therebetween.

6. The display apparatus of claim 5, wherein, in the first sub-area, the sensor wiring directly contacts the sub-sensor wiring through a contact hole formed in the insulating layer.

7. The display apparatus of claim 5, wherein, in the second sub-area, the sensor wiring is disposed on a top surface of the sub-sensor wiring.

8. The display apparatus of claim 5, wherein the touch sensor layer comprises:
a first insulating layer disposed on the encapsulation layer;
a first conductive layer disposed on the first insulating layer;
a second insulating layer disposed on the first conductive layer; and
a second conductive layer disposed on the second insulating layer,
wherein the insulating layer is the second insulating layer of the touch sensor layer.

9. The display apparatus of claim 8, wherein
the sensor wiring and the second conductive layer include a same material, and
the sub-sensor wiring and the first conductive layer include a same material.

10. The display apparatus of claim 8, wherein the first insulating layer is disposed in the display area, the first area, and the bendable area.

11. The display apparatus of claim 10, wherein the sub-sensor wiring is disposed on the first insulating layer and extends into the bendable area.

12. The display apparatus of claim 8, wherein the first insulating layer is disposed in the display area and the first area but not in the bendable area.

13. The display apparatus of claim 8, wherein the second insulating layer is disposed in the display area and the first area but not in the bendable area.

14. The display apparatus of claim 8, wherein an edge of the first insulating layer is closer to the bendable area than an edge of the second insulating layer.

15. The display apparatus of claim 12, wherein the sensor wiring directly contacts a top surface and a side surface of the sub-sensor wiring and a side surface of the first insulating layer.

16. The display apparatus of claim 15, wherein the sensor wiring directly contacts a side surface of the second insulating layer.

17. The display apparatus of claim 15, wherein the sensor wiring comprises
a first wiring portion disposed on a top surface of the second insulating layer, and
a second wiring portion disposed on the top surface of the sub-sensor wiring and spaced apart from a side surface of the second insulating layer,
wherein the first wiring portion and the second wiring portion are electrically connected to each other through the sub-sensor wiring.

18. The display apparatus of claim 8, wherein the second insulating layer comprises a first portion and a second portion that have different thicknesses, wherein
the second portion of the second insulating layer is located closer to the bendable area than the first portion of the second insulating layer, and
a thickness of the second portion of the second insulating layer is less than a thickness of the first portion of the second insulating layer.

19. The display apparatus of claim 1, further comprising an organic layer disposed on the touch sensor layer and that covers the sensor wiring in the bendable area.

20. A display apparatus, comprising:
a substrate that includes a display area, a peripheral area located outside the display area, a bendable area located in the peripheral area, and a first area located between the display area and the bendable area;
a power supply wiring that extends from the display area to the first area and the bendable area;
a sensor wiring of a touch sensor layer, wherein the sensor wiring extends from the display area to the first area and the bendable area and overlaps the power supply wiring; and
a sub-sensor wiring of the touch sensor layer, wherein the sub-sensor wiring is disposed under the sensor wiring in the first area and overlaps the sensor wiring,
wherein the first area comprises a first sub-area and a second sub-area between the first sub-area and the bendable area,
wherein, in the first sub-area, the sensor wiring overlaps the sub-sensor wiring with an insulating layer interposed therebetween.
